(19) United States
(12) Patent Application Publication
(10) Pub. No.: US 2007/0188355 A1
(43) Pub. Date: Aug. 16, 2007

(54) Cryptographic logic circuits and method of performing logic operations

(76) Inventor: Yoo-Jin Baek, Yongin-si (KR)

Correspondence Address: HARNESS, DICKEY & PIERCE, P.L.C., P.O. BOX 8910, RESTON, VA, 20195, US

(21) Appl. No.: 11/334,430

(22) Filed: Jan. 19, 2006

(30) Foreign Application Priority Data
Jan. 27, 2005 (KR) 2005-07705

(51) Int. Cl. H03M 7/34

(52) U.S. Cl. 341/51

(57) ABSTRACT

Example embodiments of the present invention disclose a cryptographic logic circuit, which may include a first logic unit configured to execute at least one logic operation for a plurality of data pairs, the data pairs including random data and random masking data, and a second logic unit configured to execute a logic operation for the results of the first logic unit. Also, the example embodiments of the present invention, which may a method of performing a logic operation in a cryptographic logic circuit including converting a plurality of input data and random data into a plurality of random masking data, executing a first logic operation on the random data and random masking data, executing a second logic operation on the output of the first logic operation, and outputting the result of the second logic operation random masking data.

### CLAIM OF PRIORITY

A claim of priority is made under 35 U.S.C. 119 of Korean Patent Application 2005-07705 filed on Jan. 27, 2005, the entire contents of which are hereby incorporated by reference.

### BACKGROUND

Example embodiments of the present invention relate to cryptographic systems. More particularly, example embodiments of the present invention relate to a cryptographic logic circuits and methods of performing logic operations against power analysis attacks.

Various cryptographic technologies are capable of retrieving private information, for example, secret keys by measuring power consumption and/or operation times during an operation. Information leaking out during a cryptographic algorithm is known as side channel information, and attacks using side channel information are known as side channel attacks. Side channel attacks may be classified as timing attacks, fault insertion attacks, and power analysis attacks. Power analysis attacks may be further classified as simple power analysis (SPA) and differential power analysis (DPA).

FIG. 1 is a schematic diagram illustrating a conventional cryptographic system and illustrating an example of a power analysis attack.

Referring to FIG. 1, during a cryptographic algorithm for a low power system, for example, a smart card having a secret key embedded therein, an attacker may monitor features of transient voltage (or current) variations of an IC chip of the smart card and then read binary codes involved in various information.

A SPA may directly attack a secret key embedded in a smart card by monitoring power consumption pattern of a cryptographic processor operating in the smart card. A DPA may use statistical analysis and/or error correction techniques to retrieve information correlative with a secret key from a collected power consumption data. A DPA may be used to retrieve the secret key with just a few devices (e.g., oscillator, etc.) capable of monitoring voltage variations. A DPA may also carry out fabrication and modulation as well as information analysis by means of statistical analysis. Therefore, it may be important to protect the secret information from the DPA. As a protection scheme against the DPA, a random masking technique may be employed. A random masking technique may be effective against a DPA.

A random masking scheme may set a cryptographic algorithm after executing a logic operation with input data and random data. A random masking scheme arranges the input data as a plaintext to be randomized. A random masking scheme may change power consumption features during the cryptographic algorithm even if the same value as the input data may be applied thereto. Thus, it may be possible to prevent secret information from being leaked. There are various methods of randomly masking input data, for example, a logic XOR operation with input data and random data. Assuming, for example, that input data is P and random data is R, random masking data may be set to P⊕R. In order to conduct an operation necessary for the input data as well as secure against a DPA, the operation needs to maintain data, which may arise from the procedure of processing a cryptographic algorithm, in the form of random masking pattern. Data in a form of a random masking pattern or a random masking data means data in which the random data may be combined with an operation result of the input data or a plurality of the input data.

For example, in a cryptographic algorithm, which logically XOR-operating (XORing), a plaintext P and a key K, and a random masking data of the plaintext P, for example, P⊕R, may be used instead of the plaintext P in the XOR operation to protect against the DPA. In this case, the logic XOR operation with the random masking data P⊕R and the key K results in (P⊕R)⊕K. The logic XOR operation permits a combination rule, the result may be rewritten into (P⊕R)⊕=(P⊕K)⊕R. As a result, it may be possible to obtain the result of the logic XOR operation, P⊕K, without disclosing information of the plaintext P. Further, the logic XOR operation result P⊕K need not be disclosed, if the logic XOR operation is not the last operation of the cryptographic algorithm, the random masking method may be sufficient to the condition because its output value may be formed in (P⊕K)⊕R. This method may also be known as a block cryptographic technique.

However, although such a cryptographic technique may be applicable to a logic XOR operation, it may not be possible to apply this technique directly to a cryptographic algorithm employing, for example, a logic AND operation with a plaintext P and a secret key K. A logic AND operation, to which the block cryptographic technique may be applied, may also generate a result (P⊕R)·K from a random masking data (P⊕R) and the secret key K. However, because a combination rule is not available for logic AND operation, it may not be possible to get (P⊕R)·K=(P·K)⊕R.

Therefore, it may not be possible for a random masking technique to be applicable to a cryptographic algorithm (e.g., including a composite logic operation mixed with Boolean and arithmetic operations) employing one or more logic operations (e.g., AND, OR, etc.) not available with a combination rule.

### SUMMARY OF THE INVENTION

In an example embodiment of the present invention, a cryptographic logic circuit may include a first logic unit configured to execute at least one logic operation for a plurality of data pairs, the data pairs including random data and random masking data, and a second logic unit configured to execute a logic operation for the results of the first logic unit.

In another example embodiment of the present invention, a cryptographic logic arithmetic circuit of a full adder may include a plurality of first logic units, each of the first logic units including a plurality of AND gates, and a plurality of second logic units, each of the second logic units including a plurality of XOR gates. Each of the AND gates of are configured to receive at least two input of first and second random data, first and second random masking data, first carry random data, and first carry random masking data, and each of the XOR gates are configured to receive at least three inputs of the output of the respective plurality of first logic units, the first carry random data and first carry random masking data.

In an example embodiment of the present invention, a method of performing a logic operation in a cryptographic logic circuit may include converting a plurality of input data and random data into a plurality of random masking data, executing a first logic operation on the random data and random masking data, executing a second logic operation on the output of the first logic operation, and outputting the result of the second logic operation random masking data.

### BRIEF DESCRIPTION OF THE DRAWINGS

The accompanying drawings are included to provide a further understanding of example embodiments of the present invention, and are incorporated in and constitute a part of this specification. The drawings illustrate example embodiments of the present invention and, together with the description, serve to explain example embodiments of the present invention. In the drawings:

FIG. 1 is a schematic diagram illustrating a conventional cryptographic system;

FIG. 2 is a flow chart illustrating a logic operation procedure in accordance with an example embodiment of the present invention;

FIGS. 3A through 3D and 4A through 4D are circuit diagrams illustrating cryptographic logic circuits in accordance with example embodiments of the present invention;

FIGS. 5A and 5B are circuit diagrams illustrating cryptographic logic circuits in accordance with other example embodiments of the present invention;

FIGS. 6A through 6D and 7A through 7D are circuit diagrams illustrating cryptographic logic circuits in accordance with other example embodiments of the present invention;

FIGS. 8A and 8B are circuit diagrams illustrating logic NOR cryptographic logic circuits in accordance with example embodiments of the present invention;

FIG. 9 is a circuit diagram illustrating a cryptographic logic circuit in accordance with an example embodiment of the invention;

FIG. 10 is a circuit diagram illustrating a cryptographic logic circuit in accordance with an example embodiment of the present invention;

FIG. 11 is a circuit diagram illustrating a cryptographic logic circuit in accordance with an example embodiment of the present invention; and

FIGS. 12 through 16 are circuit diagrams illustrating arithmetic cryptographic logic circuits according to example embodiments of the present invention.

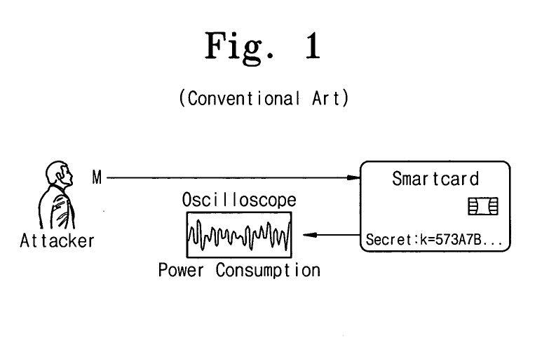

### DETAILED DESCRIPTION OF EXAMPLE EMBODIMENTS

Example embodiments of the present invention will be described below in more detail with reference to the accompanying drawings. The present invention may, however, be embodied in different forms and should not be constructed as limited to the example embodiments set forth herein. Rather, these example embodiments are provided as working examples. Like numerals may refer to like elements throughout the specification.

Cryptographic logic circuits and methods to perform a logic operation may adapt a random masking technique for logic operations for AND, OR, NAND, NOR, XOR, XNOR, and NOT. Cryptographic logic circuits having the above described configuration may be applicable to a composite logic operation mixed with more than two logic operations (e.g., Boolean and arithmetic operations), to protect a cryptographic algorithm or an arithmetic operation unit against a power analysis attack.

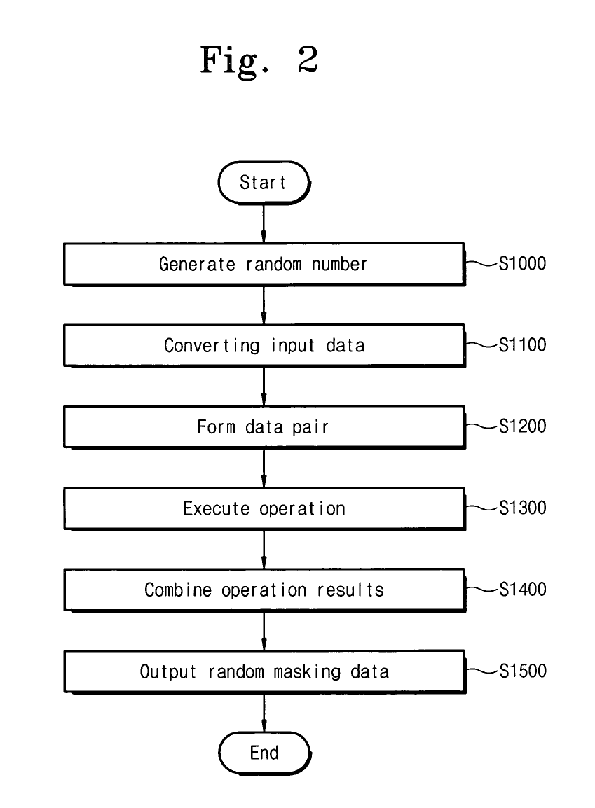

FIG. 2 is a flow chart illustrating a logic operation procedure in accordance with an example embodiment of the present invention. The logic operation illustrated in FIG. 2 may be operable with a random masking scheme having security against a power analysis attack. The logic operation may also be applicable for circuits (or units), which may or may not be available with a combination rule. In example embodiments of the preset invention, a cryptographic logic circuit may be configured to conduct at least one logic operation among AND, OR, NAND, NOR, XOR, XNOR, and NOT.

Referring to FIG. 2, the logic operation method in a cryptographic logic circuit (or unit) according to an example embodiment of the present invention may generate random data, e.g., R and S (S1000). The random data R and S generated at S1000 are input for a logic XOR operation together with input data X and Y. After completing the logic XOR operation, random masking data X′ and Y′ may be generated (S1100). The first random masking data X′ may be obtained from the logic XOR operation with a first input data X and the first random data R, while the second random masking data Y′ may be obtained from a logic XOR operation with the second input data Y and the second random data R.

The random masking data X′ and Y′ and the random data R and S may be combined to form data pairs (X′, Y′), (X′, S), (R, Y′), (R, S), and so forth (S1200). One or more logic operations (first logic operation) may be carried out on data pairs (X′, Y′), (X′, S), (R, Y′), (R, S), and so forth (S1300). In S1300, in addition to an XOR logic circuit, an AND, OR, NAND, and NOR logic circuit may be available to conduct logic operations. During S1300, one or more logic operations may be carried out for the data pairs (X′, Y′), (X′, S), (R, Y′), (R, S). After executing one or more logic operations for the data pairs, results of the operations may be combined to be matched with the logic operation value to be used in a cryptographic logic circuit (S1400). In S1400, at least one of logic XOR and XNOR operations (second logic operation) may be carried out for the combined results of the first logic operation. A result of the second logic operation, may be formed in a pattern of the random masking data. Output data in the form of the random masking data may be output as a logic operation result of the cryptographic logic circuit (S1500).

The cryptographic logic circuits may be applicable to a composite logic operation (e.g., mixed Boolean and arithmetic operations for one of the logic operations). Output data and data used in logic operations may be composed in a form of random masking data. The operation unit with this configuration may be applicable to an arithmetic cryptographic logic circuit executing at least one of addition, subtraction, multiplication, and division. Both the result of the logic operation and data to be used in the arithmetic operation may be formed in a pattern of the random masking data, so that the original data may not be disclosed by power analysis attacks. In addition, the cryptographic logic circuits may be able to be constructed in a hardware architecture each capable of performing a logic operation (AND, OR, NAND, NOR, XOR, XNOR, and NOT). Therefore, it may be possible to design a cryptographic system capable executing a complicated algorithm by combining various cryptographic logic circuits (or units) against the power analysis attacks.

Example embodiments of various cryptographic logic circuits applicable to the logic operations scheme are illustrated in FIG. 2. The cryptographic logic circuits described herein below may be applicable to a random masking scheme to secure against power analysis attacks, and compatible with either logic operations available or unavailable to the combination rule. The cryptographic logic circuits may be configured to execute one of logic operations AND, OR, NAND, NOR, XOR, XNOR, and NOT.

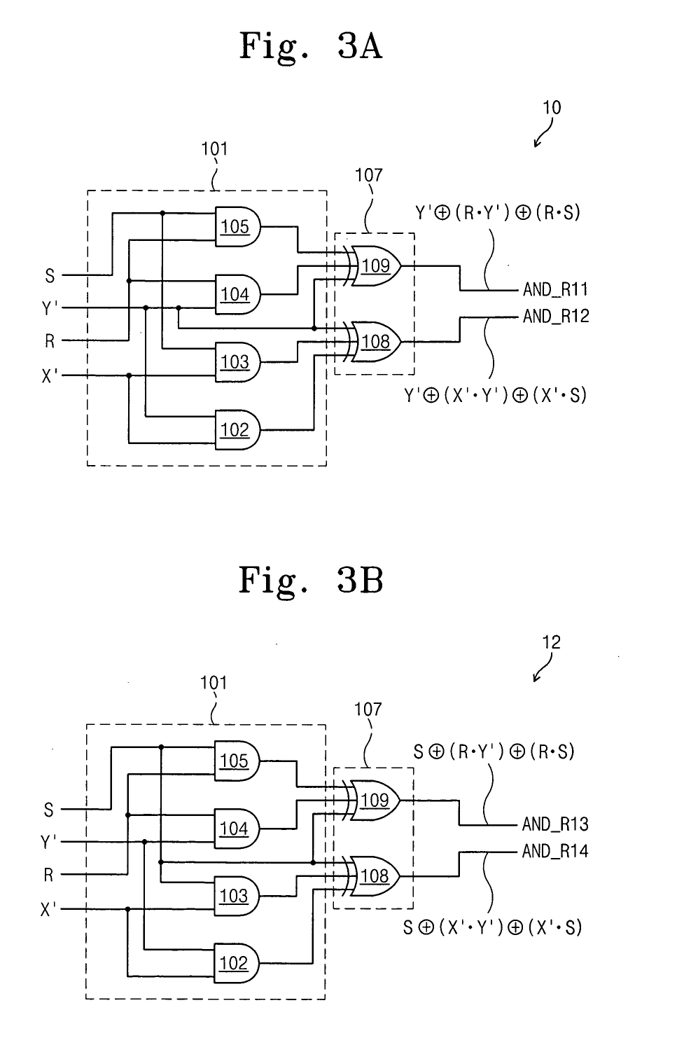

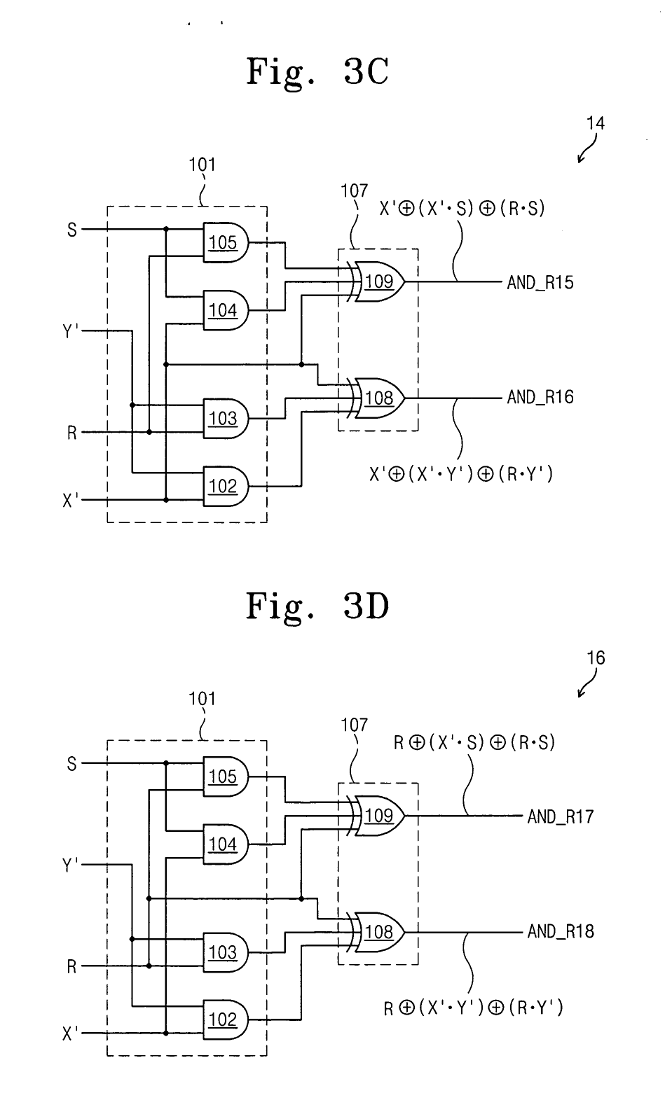

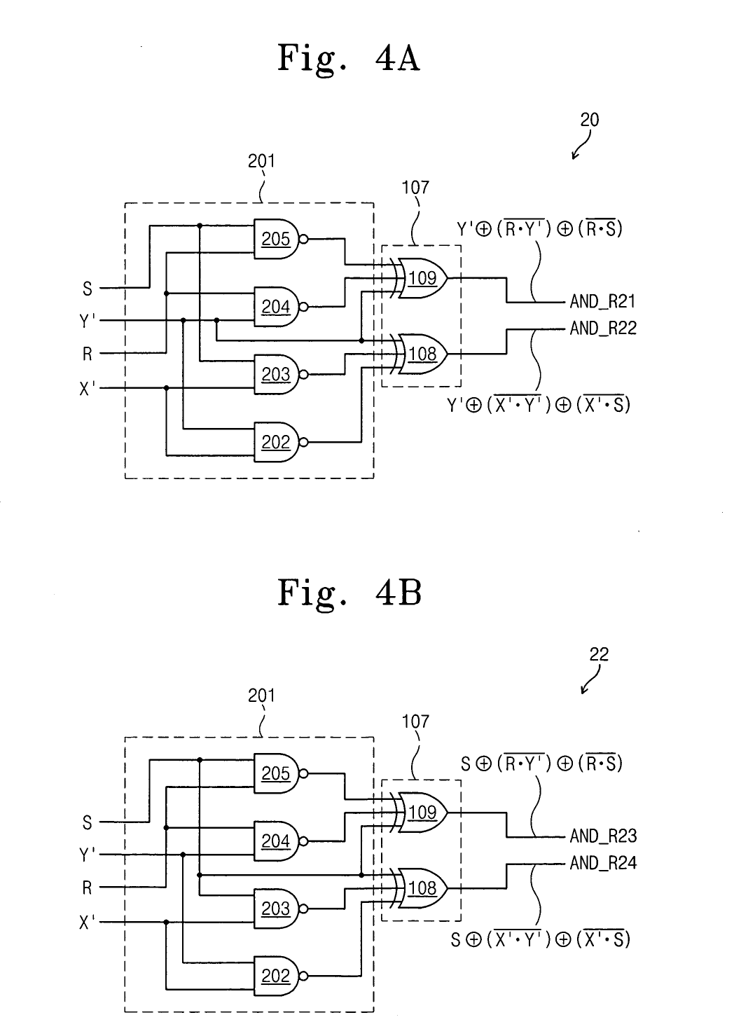

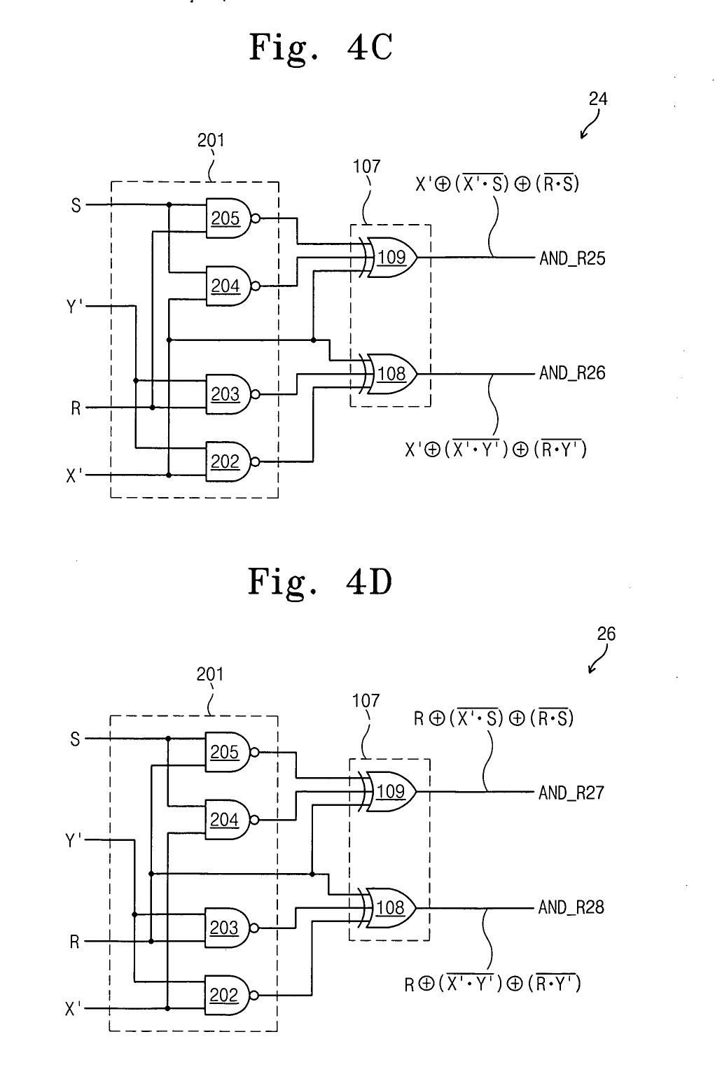

FIGS. 3A through 3D and 4A through 4D are circuit diagrams illustrating cryptographic AND logic circuits, 10˜16 and 20˜26, in accordance with example embodiments of the present invention.

Referring to FIG. 3A, a cryptographic AND logic circuit 10 may be comprised of a first logic operation unit 101 and a second logic operation unit 107. The first logic operation unit 101 may be composed of first through fourth logic circuits 102˜105. Each of the logic circuits may be an AND gate. The first logic operation circuit 102 may execute a logic AND operation X′·Y′ with a first random masking data X′ and a second random masking data Y′. The second logic operation circuit 103 may execute a logic AND operation X′·S with the first random masking data X′ and a second random data S. The third logic operation circuit 104 may execute a logic AND operation R·Y′ with a first random data R and the second random masking data Y′. The fourth logic operation circuit 105 may execute a logic AND operation R·S with the first random data R and the second random data S. The random data R and S and the random masking data X′ and Y′ input to the first through fourth logic operation circuits 102˜105 may be randomly generated at each clock cycle. The first random masking data X′ may be a result of a logic XOR operation with the first input data X and the first random data R, while the second random masking data Y′ may be a result of a logic XOR operation with the second input data Y and the second random data S.

Results of the first through fourth logic operation circuits 102˜105 may be combined by the second logic operation unit 107, and the combined results may be output in a form of block masking data. The second logic operation unit 107 may be comprised of a first logic combination circuit 108 and a second logic combination circuit 109, and each may be constructed of an XOR gate. The first logic combination circuit 108 may execute a logic XOR operation with the result of the logic AND operation by the first logic operation circuit 102, X′·Y′, the result of the logic AND operation by the second logic operation circuit 103, X′·S, and the second random masking data Y′. The second logic combination circuit 109 may execute a logic XOR operation with the result of the logic AND operation by the third logic operation circuit 104, R·Y′, the result of the logic AND operation by the fourth logic operation circuit 105, R·S, and the second random masking data Y′.

The results of the logic XOR operations by the first and second logic combination circuits 108 and 109 may be output as results of the cryptographic logic circuit 10. The logic AND operation may result from the cryptographic AND logic circuit 10, Y′⊕(R·Y′)⊕(R·S) and Y′⊕(X′·Y′)⊕(X′·S), may all be generated in a form of random masking data. If a further XOR operation is carried out for the two logic AND operation results Y′⊕(R·Y′)⊕(R·S) and Y′⊕(X′·Y′)⊕(X′·S), the required operation result X·P may be obtained.

The result may be summarized by Equation 1 as follows.

$$\begin{matrix}\begin{matrix}\{ {Y}^{′} ⊕ ( {X}^{′} \cdot {Y}^{′} ) ⊕ ( {X}^{′} \cdot S ) \} ⊕ \\ \{ {Y}^{′} ⊕ ( R \cdot {Y}^{′} ) ⊕ ( R \cdot S ) \}\end{matrix} = \{ ( {X}^{′} \cdot {Y}^{′} ) ⊕ ( {X}^{′} \cdot S ) \} ⊕ \\ \{ ( R \cdot {Y}^{′} ) ⊕ ( R \cdot S ) \} \\ = \{ {X}^{′} ( {Y}^{′} ⊕ S ) \} ⊕ \{ R ( {Y}^{′} ⊕ S ) \} \\ = ( {Y}^{′} ⊕ S ) ( {X}^{′} ⊕ R ) \\ = ( ( Y ⊕ S ) ⊕ S ) ) ( ( X ⊕ R ) ⊕ R ) ) \\ = ( Y ⊕ ( S ⊕ S ) ) ( ( X ⊕ ( R ⊕ R ) ) \\ = Y \cdot X \\ = X \cdot Y\end{matrix} \qquad [ Equation 1 ]$$

According to the cryptographic AND logic circuit 10, when the four 1-bit data, X′(=X⊕R), Y′(=Y⊕S), R, and S, are provided thereto, the data used in the operation and the data as the result of the operation, as well as the input data X and Y, are all formed in the random masking data pattern. Thus, secret information may not be disclosed during a logic operation. As the probability distribution of the intermediate calculating values is independent from the input data X and Y, it may be possible to obtain the logic operation result originally intended when the results of the cryptographic AND logic circuit 10 are each put into the logic XOR operations.

The features shown in FIGS. 3B through 3D may be modifications of the cryptographic AND logic circuit 10 illustrated in FIG. 3A. Comparing cryptographic AND logic circuits 12, 14, and 16 with the cryptographic AND logic circuits 10 of FIG. 3A, design of each circuits are similar, except for the arrangement of combination with data to be used in operation. Thus for brevity, similar features will not be described; in addition, same reference numbers are used. It should also be noted that the cryptographic AND logic circuits 12˜16 may further be modified by adjusting the various arrangement of combination with the random masking data X′ and Y′ and the random data R and S. Similar to the cryptographic AND logic circuit 10 illustrated in FIG. 3A, if an XOR operation is carried out by the cryptographic AND logic circuits 12˜16, the results obtained by each of the cryptographic AND logic circuits may be the required operation result X·Y for the two input data X and Y.

The cryptographic AND logic circuits 20˜26 illustrated in FIGS. 4A through 4D may be modifications of corresponding cryptographic AND logic circuits 10˜16 illustrated in FIGS. 3A through 3D, respectively. The cryptographic AND logic circuits 20˜26 may be constructed by substituting NAND gates for the AND gates used in the cryptographic AND logic circuits 10˜16 of FIGS. 3A through 3D. Therefore, the cryptographic AND logic circuits 20˜26 may be similar to those of FIGS. 3A through 3D, except for the structure of first logic operation units. Thus, redundant details will not be described.

As is well known by those skilled in the art, a NAND gate has a smaller size than an AND gate. Therefore, it will be understood that substituting NAND gates for AND gates enables a hardware architecture to be simpler to provide for a smaller chip size. Such reduced in hardware architecture arises from the characteristic of a logic XOR operation defined in Equation 2 as follows.
X⊕Y= X̅⊕ Y̅ [Equation 2]

The truth table X⊕Y and X̅⊕ Y̅ described in Equation 1 may be arranged as follows.

TABLE 1

| X | Y | X ⊕ Y |
|---|---|---|
| 0 | 0 | 0 |
| 0 | 1 | 1 |
| 1 | 0 | 1 |
| 1 | 1 | 0 |

TABLE 2

| X̅ | Y̅ | X̅ ⊕ Y̅ |
|---|---|---|
| 1 | 1 | 0 |
| 1 | 0 | 1 |
| 0 | 1 | 1 |
| 0 | 0 | 0 |

Referring to Equation 2, Table 1, and Table 2, the AND operation results, Y′⊕(X′·Y′)⊕(X′·S) and Y′⊕(R·Y′)⊕(R·S), may be transformed into Y′⊕ (̅X̅′̅·̅Y̅′̅)̅⊕ (̅X̅′̅·̅S̅)̅ and Y′⊕ (̅R̅·̅Y̅)̅⊕ (̅R̅·̅S̅)̅, respectively. With such a characteristic of the XOR operation, the AND gates included in the cryptographic AND logic circuit 10, for example, the logic operation circuits 102˜105 may be NAND gates 202˜205 as illustrated in FIG. 4A.

The cryptographic NAND logic circuit 22 as illustrated in FIG. 4B may be reduced from the cryptographic AND logic circuits 12 illustrated in FIG. 3B, and the cryptographic NAND logic circuit 24 illustrated in FIG. 4C may be reduced from the cryptographic AND logic circuit 14 illustrated in FIG. 3C. The cryptographic NAND logic circuit 26 illustrated in FIG. 4D may be reduced from the cryptographic AND logic circuit 16 illustrated in FIG. 3D. Thus, further description of the cryptographic NAND logic circuits 20˜26 will be omitted.

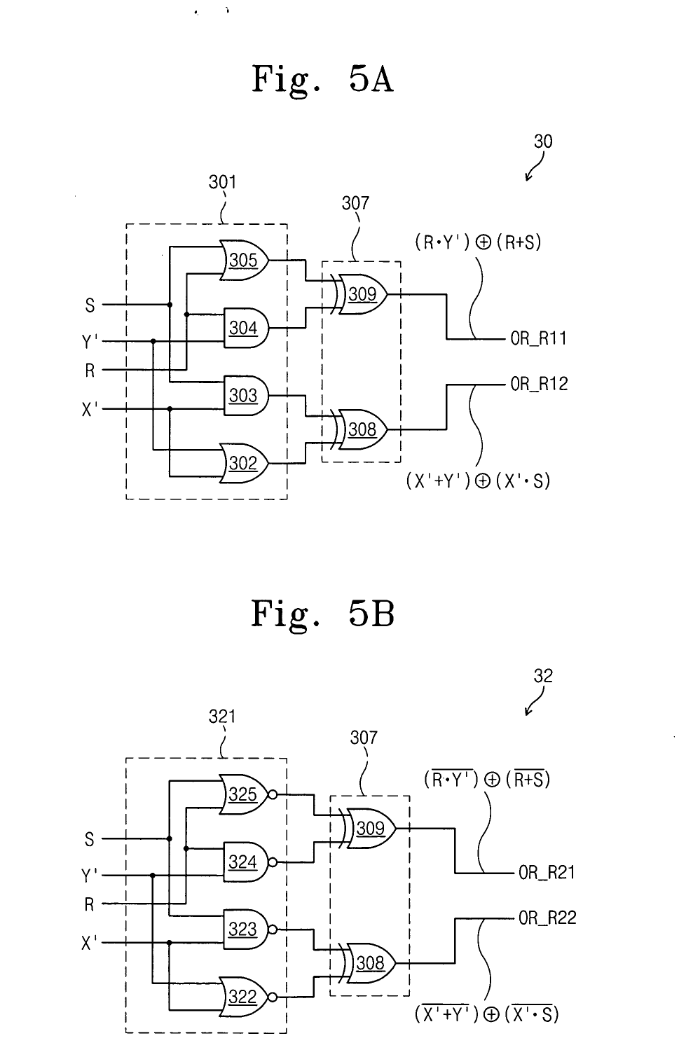

FIG. 5A and 5B are circuit diagrams illustrating cryptographic OR logic circuits 30 and 32 capable of executing logic OR operations for the first and second input data X and Y in accordance with other example embodiments of the present invention.

Referring to FIG. 5A, the OR logic circuit 30 may be comprised of a first logic operation unit 301 and a second logic operation unit 307. The first logic operation unit 301 may be composed of first through fourth logic operation circuits 302˜305. Each of the logic operations circuits 302˜305 may be either an AND gate, an OR gate, or a combination thereof. The first logic operation circuit 302 may execute a logic OR operation X′+Y′ with a first random masking data X′ and a second random masking data Y′. The second logic operation circuit 303 may execute a logic AND operation X′·S with the first random masking data X′ and a second random data S. The third logic operation circuit 304 may execute a logic AND operation R·Y′ with a first random data R and the second random masking data Y′. The fourth logic operation circuit 305 may execute a logic OR operation R+S with the first random data R and the second random data S. The random data R and S and the random masking data X′ and Y′ input to first through fourth logic operation circuits 302˜305 may be randomly generated at each clock cycle. The first random masking data X′ may be a result of a logic XOR operation with the first input data X and the first random data R, while the second random masking data Y′ may be a result of a logic XOR operation with the second input data Y and the second random data S.

The results from the first through fourth logic operation circuits 302˜305 may be combined by the second logic operation unit 307, and the combined results may be output as block masking data. The second logic operation unit 307 may be comprised of a first logic combination circuit 308 and a second logic combination circuit 309. Each of the logic combination circuits may be an XOR gate. The first logic combination circuit 308 may execute a logic XOR operation with the result of the logic OR operation by the first logic operation circuit 302, X′+Y′, and the result of the logic AND operation by the second logic operation circuit 303, X′·S. The second logic combination circuit 309 may execute a logic XOR operation with the result of the logic AND operation by the third logic operation circuit 104, R·Y′, and the result of the logic OR operation by the fourth logic operation circuit 105, R+S.

The results of the logic XOR operations by the first and second logic combination circuits 308 and 309 may be output as results of the cryptographic OR logic circuit 30. The logic AND operation results from the cryptographic OR logic circuit 30, (X′+Y′)⊕(X′·S) and (R·Y′)⊕(R+S), may all be generated in the form of random masking data. If a further XOR operation is carried out for the two logic OR operation results (X′+Y′)⊕(X·S) and (R·Y′)⊕(R+S), the required operation result X+Y may be required.

Referring to FIG. 5B, the logic OR operation circuit 30 may be modified to form the cryptographic OR logic circuit 32 by replacing AND gates with NAND gates. Therefore, the cryptographic OR logic circuits 32 may be similar to the cryptographic OR logic circuit 30 of FIG. 5A. Therefore, details of similar elements and/or operations will be omitted. Hardware architecture reduction with the cryptographic OR logic circuit 32 arises from the characteristic of the logic XOR operation defined in Equation 2.

In the cryptographic OR logic circuits 30 and 32 shown in FIGS. 5A and 5B, when a four 1-bit data, X′(=X⊕R), Y′(=Y⊕S), R, and S, are given thereto, the data used in the operation and the data as the result of the operation, as well as the input data X and Y, may all be formed in a random masking data pattern. Thus, there may not be a disclosure of secret information during a logic operation by a power analysis attack. As the probability distribution of the intermediate calculating values may be independent from the input data X and Y, it may be possible to obtain the logic operation result originally intended when the results of the cryptographic OR logic circuits 30 and 32 are each put into the logic XOR operations.

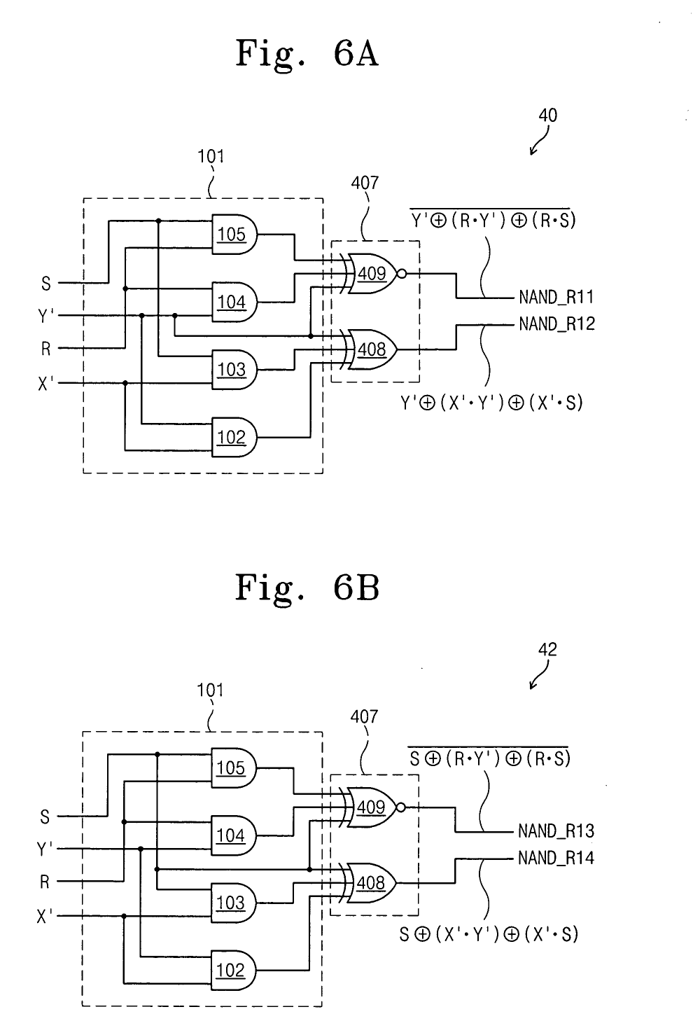

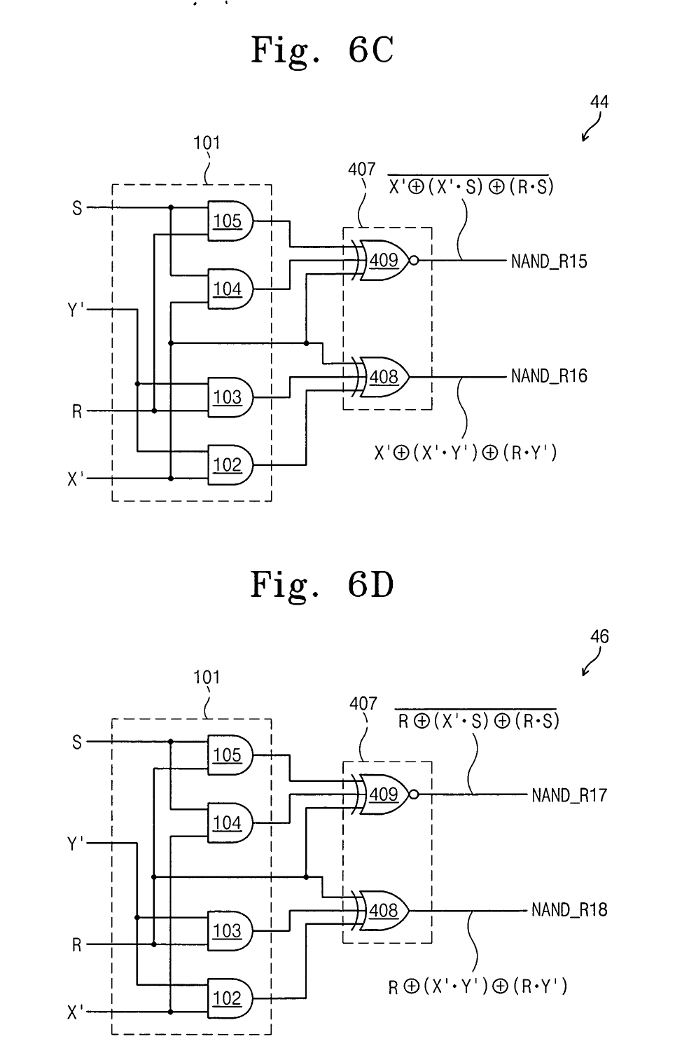

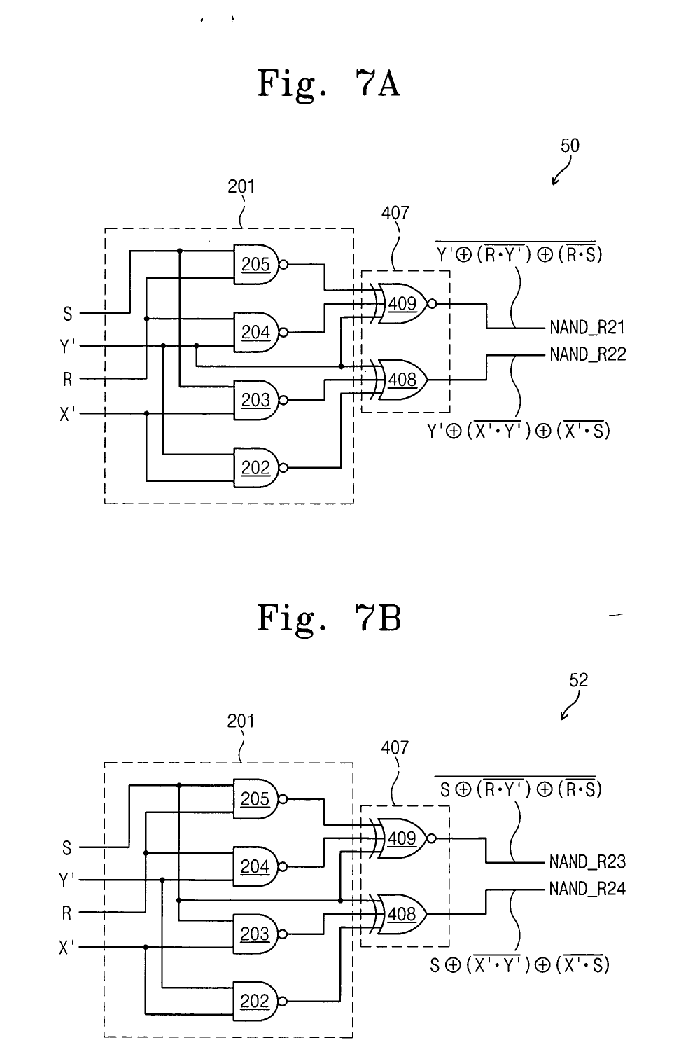

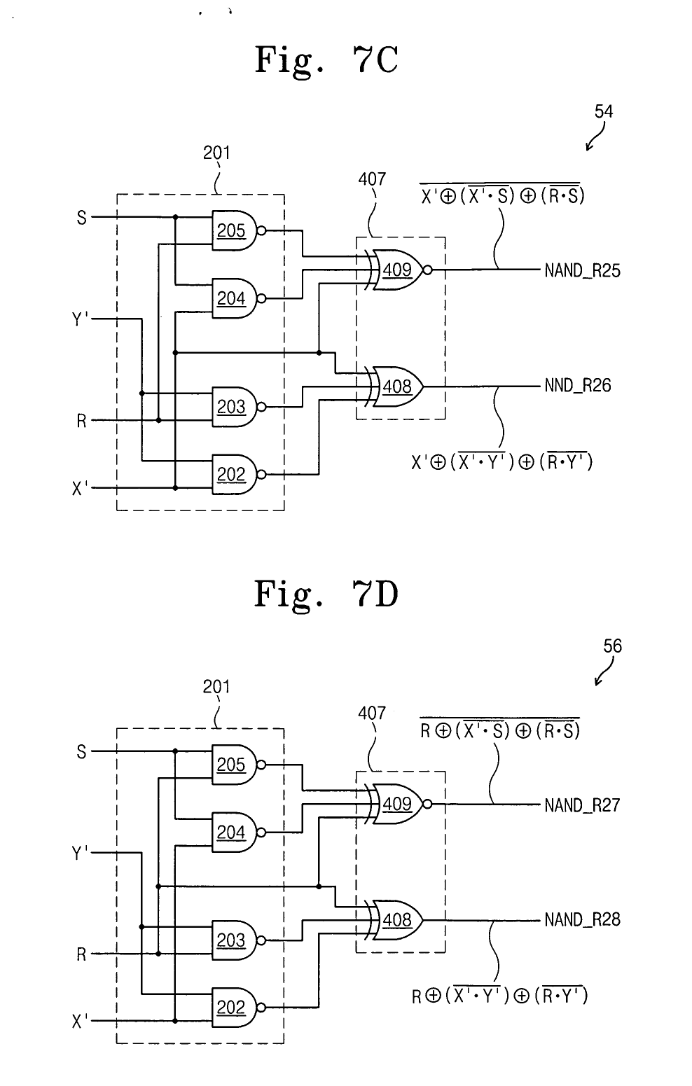

FIGS. 6A through 6D and 7A through 7D are circuit diagrams illustrating cryptographic NAND logic circuits, 40˜46 and 50˜56, respectively, in accordance with example embodiments of the present invention, capable of executing logic NAND operations for first and second input data X and Y. Comparing the cryptographic NAND logic circuit 40˜46 and 50˜56 illustrated in FIGS. 6A through 7D with the cryptographic AND logic circuit 10˜16 and 20˜26 illustrated in FIGS. 3A through 4D, the circuits are similar to each other, except for a second logic operation units 407. Therefore, further detail description of similar elements/or and operations will be omitted.

According to the cryptographic NAND logic circuit 40˜46 and 50˜56, when four 1-bit data, X′(=X⊕R), Y′(=⊕S), R, and S, are given thereto, the data used in the operation and the data as the result of the operation, as well as the input data X and Y, may all be formed in a random masking data pattern. Thus, secret information may not be disclosed during the logic operation against power analysis attacks. As the probability distribution of the intermediate calculating values may be independent from input data X and Y, it may be possible to obtain the logic operation result originally intended when the results of the cryptographic NAND logic circuits 40˜46 and 50˜56 are each put into the logic XOR operations.

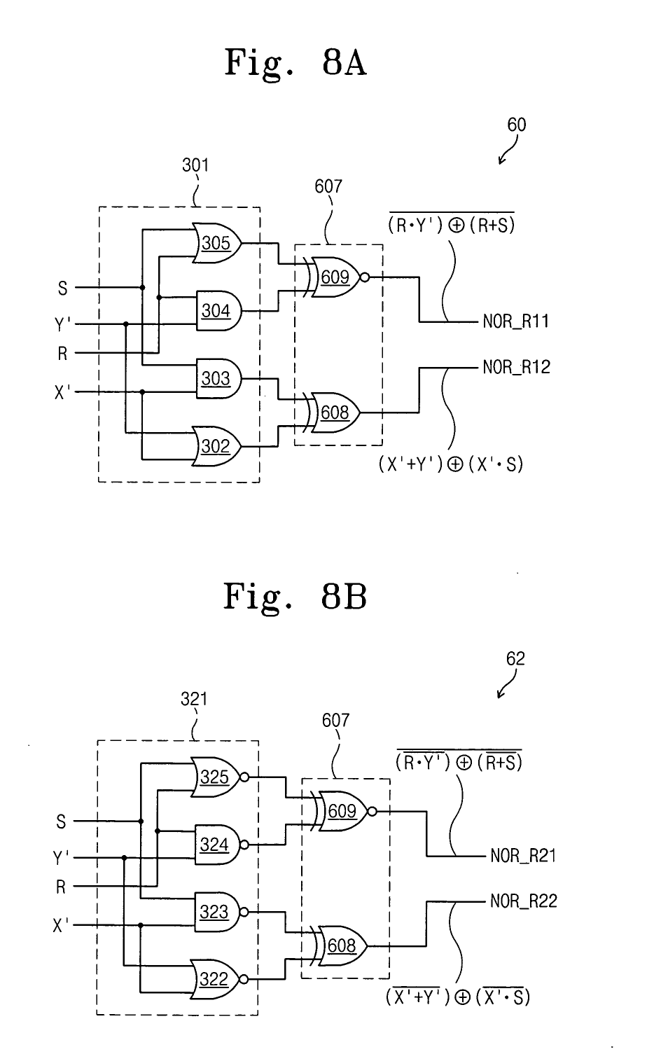

FIG. 8A and 8B are circuit diagrams illustrating cryptographic NOR logic circuits 60 and 62 in accordance with another example embodiments of the present invention, capable of executing logic NOR operations for first and second input data X and Y. The cryptographic NOR logic circuits 60 and 62 illustrated in FIGS. 8A and 8B may output results of the logic NOR operations, altering the logic combinations of the first logic operation units 301 and 321 of the cryptographic OR logic circuits 30 and 32 as illustrated in FIGS. 5A and 5B. The cryptographic NOR logic circuits 60 and 62 of FIGS. 8A and 8B may be similar to the cryptographic OR logic circuits 30 and 32, except for the construction of the second logic operation units 607. Thus, further detail description of similar elements and/or operations will be omitted.

For example, according to the cryptographic NOR logic circuits 60 and 62 as illustrated in FIGS. 8A and 8B, when four 1-bit data, X′(=X⊕R), Y′(=Y⊕S), R, and S, are given thereto, the data used in the operation and the data as the result of the operation, as well as the input data X and Y, may all be formed in a random masking data pattern. Thus, secret information during a logic operation may not be disclosed against power analysis attacks. As the probability distribution of the intermediate calculating values is independent from the input data X and Y, it may be possible to obtain the logic operation result originally intended when the results of cryptographic NOR logic circuits 60 and 62 are each put into the logic XOR operations.

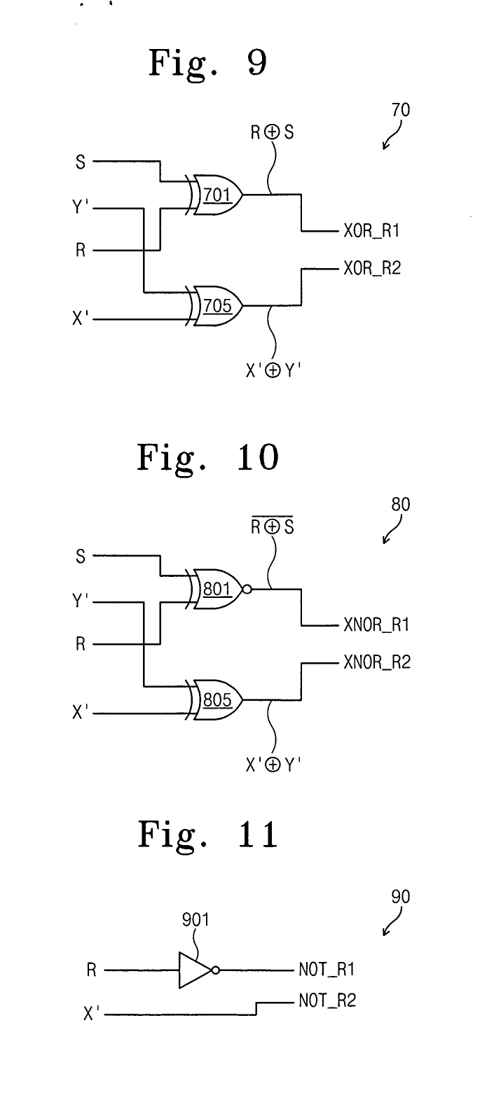

FIG. 9 is a circuit diagram illustrating a cryptographic logic circuit 70 in accordance with an example embodiment of the present invention, and FIG. 10 is a circuit diagram illustrating another cryptographic logic circuit 80 in accordance with an example embodiment of the present invention.

Referring to FIG. 9, the cryptographic logic circuit 70 may be comprised of a first logic operation unit 701 and a second logic operation unit 705. The first logic operation unit 701 may execute a logic XOR operation X′⊕Y′ with a first random masking data X′ and a second random masking data Y′. The second logic operation circuit 705 may execute a logic XOR operation R⊕S with a first random data R and a second random data S. The results of the logic XOR operations by the first and second logic operation circuits 701 and 705, X′⊕Y′ and R⊕S, may be output as results of the cryptographic logic circuit 70.

Referring to FIG. 10, the cryptographic logic circuit 80 may be comprised of a first logic operation unit 801 and a second logic operation unit 805. The first logic operation unit 801 may execute a logic XOR operation X′⊕Y′ with a first random masking data X′ and a second random masking data Y′. A second logic operation circuit 805 may execute a logic XOR operation R̅⊕̅S̅ with a first random data R and a second random data S. The results of the logic XOR operations by the first and second logic operation circuits 801 and 805, X′⊕Y′ and R̅⊕̅S̅, may be output as results of the cryptographic logic circuit 80.

According to the cryptographic logic circuits 70 and 80, when four 1-bit data, X′(=X⊕R), Y′(=Y⊕S), R, and S, are given thereto, the data used in the operation and the data as the result of the operation, as well as the input data X and Y, may all be formed in the random masking data pattern. Therefore, secret information may not be disclosed during a logic operation against power analysis attacks. In this case, as the probability distribution of the intermediate calculating values is independent from the input data X and Y, it may be possible to obtain the logic operation result originally intended when the results of the cryptographic logic circuits 70 and 80 are each put into the logic XOR operations.

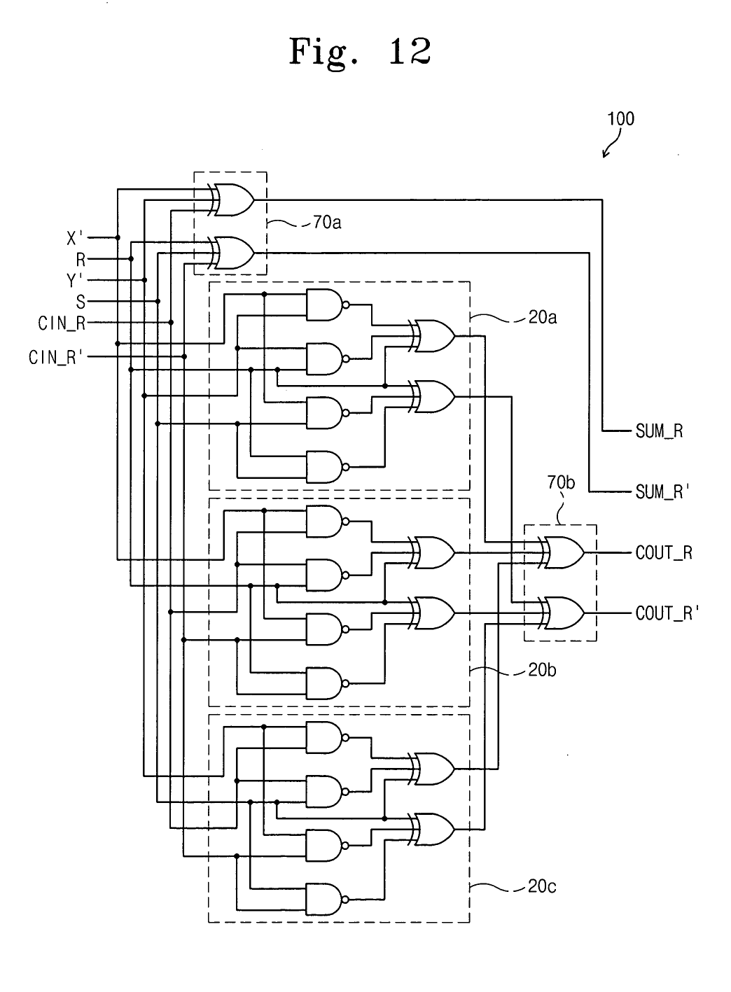

FIG. 11 is a circuit diagram illustrating a cryptographic NOT logic circuit 90 in accordance with an example embodiment of the present invention.

Referring to FIG. 11, the cryptographic NOT logic circuit may be comprised of a logic operation unit 901 that executes a logic NOT operation R̅ with a first random data R. The result of the logic NOT operations by the logic operation circuit 901, and the first random masking data X′ may be output as results of the cryptographic NOT logic circuit 90.

According to the cryptographic NOT logic circuit 90 two 1-bit data, X′(=X⊕R) and R, are given thereto, the data used in the operation and the data as the result of the operation, as well as the input data X and Y, may all be formed in the random masking data pattern. Therefore, secret information may not be disclosed during a logic operation against power analysis attacks. In this case, as the probability distribution of the intermediate calculating values is independent from the input data X and Y, it may be possible able to obtain the logic operation result originally intended when the results of the cryptographic NOT logic circuit 90 are each put into the logic XOR operation.

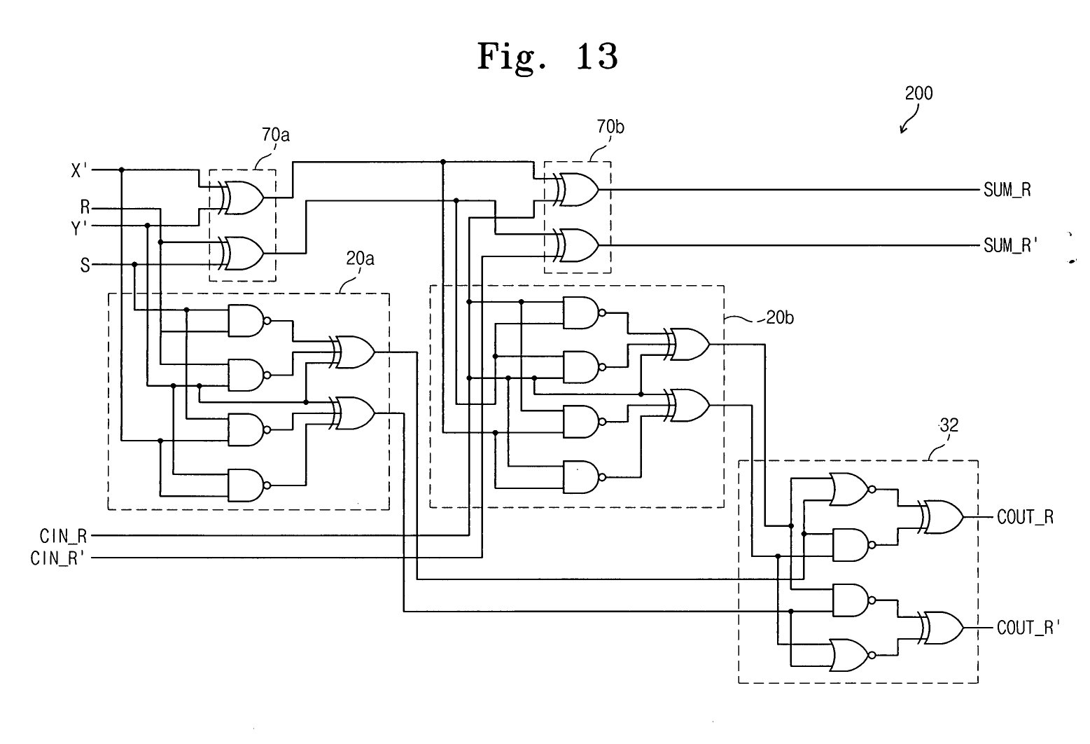

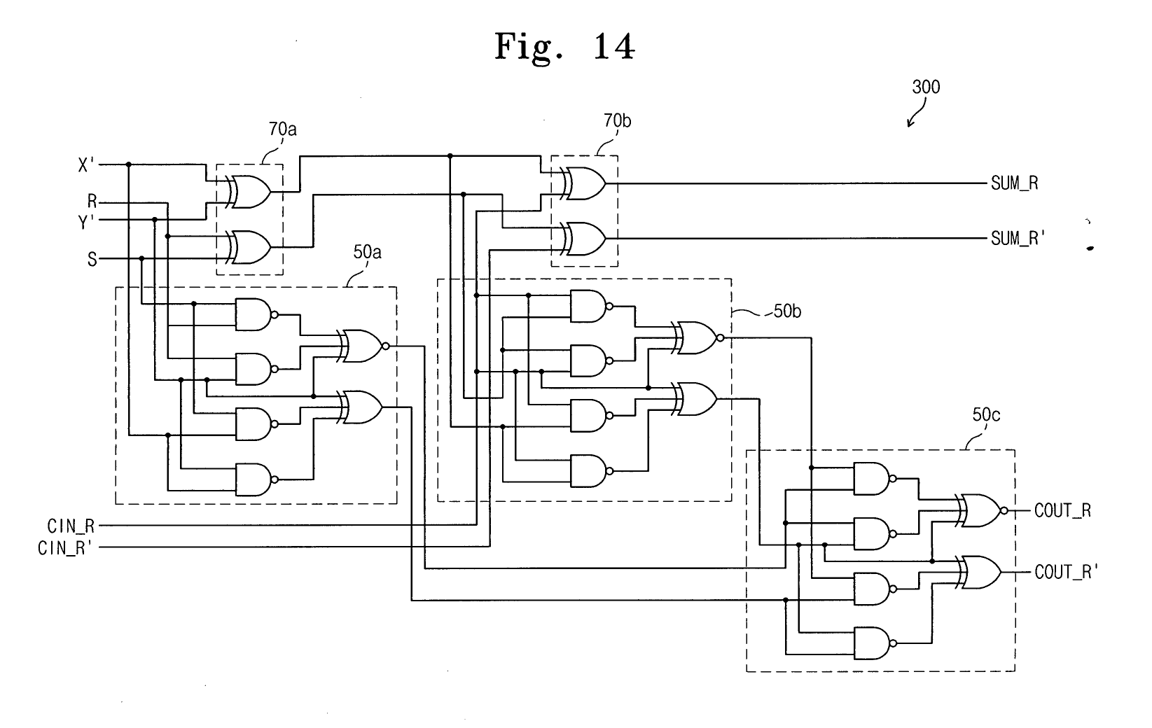

FIGS. 12 through 16 are circuit diagrams illustrating cryptographic arithmetic logic circuit according to example embodiments of the present invention. FIG. 12 illustrates a circuit structure of a full adder 100 composed of three cryptographic logic AND circuits 20a˜20c and two cryptographic XOR logic circuits 70a and 70b. FIG. 13 illustrates a circuit structure of a full adder 200 composed of two cryptographic AND logic circuits 20a and 20b, two cryptographic logic XOR circuit 70a and 70b, and a single cryptographic OR logic circuit 32. FIG. 14 illustrates a circuit structure of a full adder 300 composed of three cryptographic logic AND circuits 50a˜50c and two cryptographic XOR logic circuits 70a and 70b.

The full adders 100˜300 illustrated in FIGS. 12 through 14 may all carry out similar functions, but may be constructed in different circuit patterns according to design rules. The cryptographic logic circuits included in each of the full adders 100˜300 may also be varied. For instance, the cryptographic AND logic circuits 20a˜20c employed in the full adder 100 of FIG. 12 may be substituted each with the cryptographic AND logic circuits 10˜16 and 20˜26 illustrated in FIGS. 3A through 4D. These various constructions may also be available for other cryptographic logic circuits (e.g., cryptographic OR logic circuits, cryptographic NAND logic circuits, the logic NOR operation apparatuses, and so forth). Thus, the full adders 100˜300 illustrated in FIGS. 12 through 14 may be varied in accordance with the types of the cryptographic logic circuits employed therein.

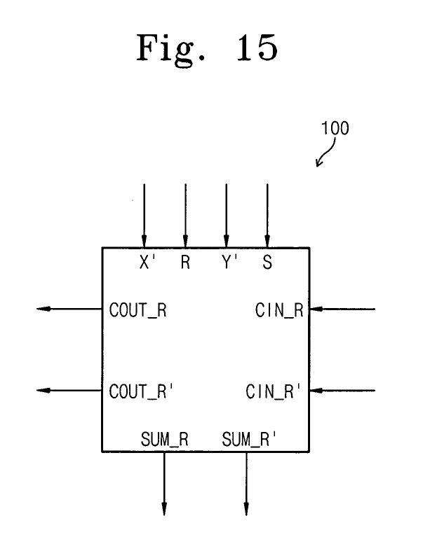

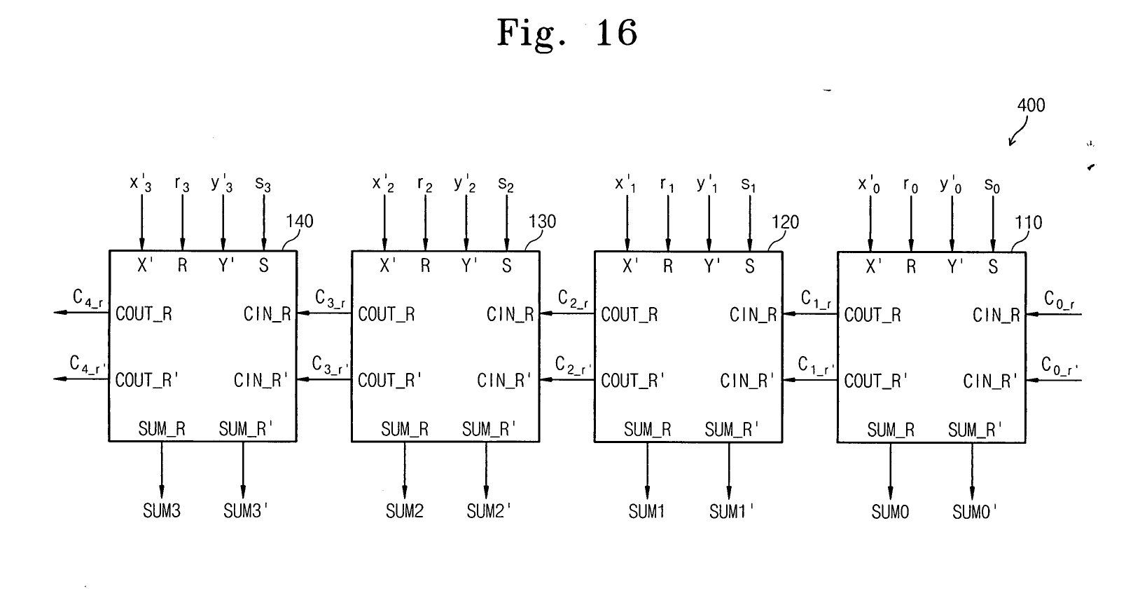

FIG. 15 illustrates a symbolic circuit diagram of the full adder 100 illustrated in FIG. 12, while FIG. 16 illustrates a ripple carry adder 400 composed of pluralities of full adders similar to that illustrated in FIG. 15. As stated above, the cryptographic logic circuits may be all adoptable to a random masking scheme. The random masking scheme may be available to a full adder 100 composed of cryptographic logic circuits, as well as a ripple carry adder 400 constructed with full adders 110˜140. Therefore, the cryptographic arithmetic logic circuit (or apparatuses) and the cryptographic logic circuit may be equipped with the security against power analysis attacks.

Although the present invention has been described in connection with example embodiments of the present invention illustrated in the accompanying drawings, example embodiments of the present invention may not be limited thereto. It will be apparent to those skilled in the art that various substitution, modifications and changes may be thereto without departing from the scope of the example embodiments of the present invention.

What is claimed is:

1. A cryptographic logic circuit, comprising:
a first logic unit configured to execute at least one logic operation for a plurality of data pairs, the data pairs including random data and random masking data; and
a second logic unit configured to execute a logic operation for the results of the first logic unit.

2. The cryptographic logic circuit as set forth in claim 1, wherein the first logic unit include:
a first AND gate configured to execute a first logic AND operation with first and second random masking data;
a second AND gate configured to execute a second logic AND operation with the first random masking data and second random data;
a third AND gate configured to execute a logic third AND operation with first random data and the second random masking data; and
a fourth AND gate configured to execute a logic fourth AND operation with the first and second random data.

3. The cryptographic logic circuit as set forth in claim 2, wherein the second logic unit includes:
a first XOR gate configured to execute a first logic XOR operation with the output of the first AND gate, the second AND gate, and the second random masking data; and
a second XOR gate configured to execute a second logic XOR operation with the output of the third AND gate, the fourth AND gate, and the second random masking data.

4. The cryptographic logic circuit as set forth in claim 1, wherein the first logic unit include:
a first AND gate configured to execute a first logic AND operation with first and second random masking data;
a second AND gate configured to execute a second logic AND operation with the first random masking data and second random data;
a third AND gate configured to execute a third logic AND operation with the second masking data and first random data; and
a fourth AND gate configured to execute a fourth logic AND operation with the first and second random data.

5. The cryptographic logic circuit as set forth in claim 4, wherein the second logic unit includes:
a first XOR gate configured to execute a first logic XOR operation with the output of the first AND gate, the second AND gate, and the second random data; and
a second XOR gate configured to execute a second logic XOR operation with the output of the third AND gate, the fourth AND gate, and the second random data.

6. The cryptographic logic circuit as set forth in claim 1, wherein the first logic unit include:
a first AND gate configured to execute a first logic AND operation with first and second random masking data;
a second AND gate configured to execute a second logic AND operation with the second random masking data and first random data;
a third AND gate configured to execute a third logic AND operation with the second masking data and second random data; and
an fourth AND gate configured to execute a fourth logic AND operation with the first and second random data.

7. The cryptographic logic circuit as set forth in claim 6, wherein the second logic unit includes:
a first XOR gate configured to execute a first logic XOR operation with the output of the first AND gate, the second AND gate, and the first random masking data; and
a second XOR gate configured to execute a second logic XOR operation with the output of the third AND gate, the fourth AND gate, and the first random masking data.

8. The cryptographic logic circuit as set forth in claim 6, wherein the second logic unit includes:
a first XOR gate configured to execute a first logic XOR operation with the output of the first AND gate, the second AND gate, and the first random data; and
a second XOR gate configured to execute a second logic XOR operation with the output of the third AND gate, the fourth AND gate operation, and the first random data.

9. The cryptographic logic circuit as set forth in claim 1, wherein the first logic unit include:
a first NAND gate configured to execute a first logic NAND operation with first and second random masking data;
a second NAND gate configured to execute a second logic NAND operation with the first random masking data and second random data;
a third NAND gate configured to execute a third logic NAND operation with first random data and the second random masking data; and
a fourth NAND gate configured to execute a fourth logic NAND operation with the first and second random data.

10. The cryptographic logic circuit as set forth in claim 9, wherein the second logic unit includes:
a first XOR gate configured to execute a first logic XOR operation with the output of the first NAND gate, the second NAND gate, and the second random masking data; and
a second XOR gate configured to execute a second logic XOR operation with the output of the third NAND gate, the fourth NAND gate operation, and the second random masking data.

11. The cryptographic logic circuit as set forth in claim 1, wherein the first logic unit include:
a first NAND gate configured to execute a first logic NAND operation with first and second random masking data;
a second NAND gate configured to execute a second logic NAND operation with second random data and the first random masking data;
a third NAND gate configured to execute a third logic NAND operation with the first random data and second random masking data; and
a fourth NAND gate configured to execute a fourth logic NAND operation with the first and second random data.

12. The cryptographic logic circuit as set forth in claim 11, wherein the second logic unit:
a first XOR gate configured to execute a first logic XOR operation with the output of the first NAND gate, the second NAND gate, and the second random data; and
a second XOR gate configured to execute a second logic XOR operation with the output of the third NAND gate, the fourth NAND gate, and the second random data.

13. The cryptographic logic circuit as set forth in claim 1, wherein the first logic unit include:
a first NAND gate configured to execute a first logic NAND operation with first and second random masking data;
a second NAND gate configured to execute a second logic NAND operation with first random data and the second random masking data;
a third NAND gate configured to execute a third logic NAND operation with the second random masking data and second random data; and
a fourth NAND gate configured to execute a fourth logic NAND operation with the first and second random data.

14. The cryptographic logic circuit as set forth in claim 11, wherein the second logic unit:
a first XOR gate configured to execute a first logic XOR operation with the output of the first NAND gate, the second NAND gate, and the first random masking data; and
a second XOR gate configured to execute a second logic XOR operation with the output of the third NAND gate, the fourth NAND gate, and the first random masking data.

15. The cryptographic logic circuit as set forth in claim 11, wherein the second logic unit:
a first XOR gate configured to execute a first logic XOR operation with the output of the first NAND gate, the second NAND gate, and the first random data; and
a second XOR gate configured to execute a second logic XOR operation with the output of the third NAND gate, the fourth NAND gate, and the first random data.

16. The cryptographic logic circuit as set forth in claim 1, wherein the first logic unit includes:
a first OR gate configured to execute a first logic OR operation with first and second random masking data;
a first AND gate configured to execute a first logic AND operation with the first random masking data and second random data;
a second OR gate configured to execute a second logic OR operation with the first and second random data; and
a second AND gate configured to execute a second logic AND operation with first random data and the second random masking data.

17. The cryptographic logic circuit as set forth in claim 16, wherein the second logic unit comprises:
a first XOR gate configured to execute a first logic XOR operation with the output of the first OR gate and the first AND gate; and
a second XOR gate configured to execute a second logic XOR operation with the output of the second OR gate and the second AND gate.

18. The cryptographic logic circuit as set forth in claim 1, wherein the first logic unit includes:
a first NOR gate configured to execute a first logic NOR operation with first and second random masking data;
a second NAND gate configured to execute a first logic NAND operation with the first random masking data and second random data;
a second NOR gate configured to execute a second logic NOR operation with the first and second random data; and
a second NAND gate configured to execute a second logic NAND operation with first random data and the second random masking data.

19. The cryptographic logic circuit as set forth in claim 18, wherein the second logic unit comprises:
a first XOR gate configured to execute a first logic XOR operation with the output of the first NOR gate and the first NAND gate; and
a second XOR gate configured to execute a second logic XOR operation with the output of the second NOR gate and the second NAND gate.

20. The cryptographic logic circuit as set forth in claim 2, wherein the second logic unit includes:
a first XOR gate configured to execute a first logic XOR operation with the output of the first AND gate, the second AND gate, and the second random masking data; and
a first XNOR gate configured to execute a first logic XNOR operation with the output of the third AND gate, the fourth AND gate, and the second random masking data.

21. The cryptographic logic circuit as set forth in claim 4, wherein the second logic unit includes:
a first XOR gate configured to execute a first logic XOR operation with the output of the first AND gate, the second AND gate, and the second random data; and
a first XNOR gate configured to execute a first logic XNOR operation with the output of the third AND gate, the fourth AND gate, and the second random data.

22. The cryptographic logic circuit as set forth in claim 6, wherein the second logic unit includes:
a first XOR gate configured to execute a first logic XOR operation with the output of the first AND gate, the second AND gate, and the first random masking data; and
a first XNOR gate configured to execute a first logic XNOR operation with the output of the third AND gate, the fourth AND gate, and the first random masking data.

23. The cryptographic logic circuit as set forth in claim 6, wherein the second logic unit includes:
a first XOR gate configured to execute a first logic XOR operation with the output of the first AND gate, the second AND gate, and the first random data; and
a first XNOR gate configured to execute a first logic XNOR operation with the output of the third AND gate, the fourth AND gate, and the first random data.

24. The cryptographic logic circuit as set forth in claim 9, wherein the second logic unit includes:
a first XOR gate configured to execute a first logic XOR operation with the output of the first NAND gate, the second AND gate, and the second random masking data; and
a first XNOR gate configured to execute a first logic XNOR operation with the output of the third NAND gate, the fourth NAND gate, and the second random masking data.

25. The cryptographic logic circuit as set forth in claim 11, wherein the second logic unit includes:
a first XOR gate configured to execute a first logic XOR operation with the output of the first NAND gate, the second NAND gate, and the second random data; and
a first XNOR gate configured to execute a first logic XNOR operation with the output of the third NAND gate, the fourth NAND gate, and the second random data.

26. The cryptographic logic circuit as set forth in claim 13, wherein the second logic unit includes:
a first XOR gate configured to execute a first logic XOR operation with the output of the first NAND gate, the second NAND gate, and the first random masking data; and
a second XOR gate configured to execute a second logic XOR operation with the output of the third NAND gate, the fourth NAND gate, and the first random masking data.

27. The cryptographic logic circuit as set forth in claim 13, wherein the second logic unit includes:
a first XOR gate configured to execute a first logic XOR operation with the output of the first NAND gate, the second NAND gate, and the first random data; and
a first XNOR gate configured to execute a first logic XNOR operation with the output of the third NAND gate, the fourth NAND gate, and the first random data.

28. The cryptographic logic circuit as set forth in claim 16, wherein the second logic unit comprises:
a first XOR gate configured to execute a first logic XOR operation with the output of the first OR gate and the first AND gate; and
a first XNOR gate configured to execute a first logic XNOR operation with the output of the second OR gate and the second AND gate.

29. The cryptographic logic circuit as set forth in claim 18, wherein the second logic unit comprises:
a first XOR gate configured to execute a first logic XOR operation with the output of the first NOR gate and the first NAND gate; and
a first XNOR gate configured to execute a first logic XOR operation with the output of the second NOR gate and the second NAND gate.

30. The cryptographic logic circuit as set forth in claim 1, wherein the first logic unit is an XOR gate configured to execute first random masking data and second random masking data, and the second logic unit is an XOR gate configured to execute first random data and second random data.

31. The cryptographic logic circuit as set forth in claim 1, wherein the first logic unit is an XOR gate configured to execute first random masking data and second random masking data, and the second logic unit is an XNOR gate configured to execute first random data and second random data.

32. The cryptographic logic circuit as set forth in claim 1, wherein the first logic unit outputs first random masking data, and the second logic unit is a NOT gate configured to execute first random data.

33. A cryptographic logic arithmetic circuit of a full adder, comprising:
a plurality of first logic units, each of the first logic units including a plurality of AND gates; and
a plurality of second logic units, each of the second logic units including a plurality of XOR gates, wherein
each of the plurality of AND gates is configured to receive at least two input of first and second random data, first and second random masking data, first carry random data, and first carry random masking data, and
each of the plurality of XOR gates is configured to receive at least three inputs of the output of the respective plurality of first logic units, the first carry random data, and first carry random masking data.

34. A method of performing a logic operation in a cryptographic logic circuit, comprising:
converting a plurality of input data and random data into a plurality of random masking data;
executing a first logic operation on the random data and random masking data;
executing a second logic operation on the output of the first logic operation; and
outputting the result of the second logic operation.

35. The method as set forth in claim 34, wherein the random data is randomly generated every clock cycle.

36. The method as set forth in claim 34, wherein converting the plurality of input data and random data into the plurality of random masking data is performed by an XOR operation

37. The method as set forth in claim 34, wherein the method is applicable to a composite logic operation including a plurality of operations,
wherein data used by the composite logic operation are formed in a random masking pattern.

38. The method as set forth in claim 34, wherein the method is executed by a composite logic operation including Boolean and arithmetic operations with a plurality of logic operations,
wherein data used by the composite logic operation are formed in a random masking pattern.

39. The method as set forth in claim 34, wherein the method is executed by an arithmetic operation including one operations among addition, subtraction, multiplication, and division, and
wherein data used by the arithmetic operation are formed in a random masking pattern.

40. The method as set forth in claim 34, wherein the first logic operation is at least on one of an AND, OR, NAND, NOR, XOR, XNOR, and NOT operation.

41. The method as set forth in claim 34, wherein the second logic operation is at least one of an XOR and XNOR operation.
